(19) United States
(12) Patent Application Publication
(10) Pub. No.: US 2024/0069112 A1
(43) Pub. Date: Feb. 29, 2024

(54) BATTERY HAZARD DETECTION

(71) Applicant: SEMICONDUCTOR COMPONENTS INDUSTRIES, LLC, Phoenix, AZ (US)

(72) Inventor: Hideo KONDO, Oizumi-machi (JP)

(73) Assignee: SEMICONDUCTOR COMPONENTS INDUSTRIES, LLC, Phoenix, AZ (US)

(21) Appl. No.: 17/821,986

(22) Filed: Aug. 24, 2022

(51) Int. Cl. G01R 31/382; G01R 31/367; G01R 31/374; G01R 31/396; H02J 7/00

(52) U.S. Cl. CPC G01R 31/382; G01R 31/367; G01R 31/374; G01R 31/396; H02J 7/0049; H02J 7/007182

(57) ABSTRACT

A method, system, and integrated circuit are provided for testing a battery within a host device for abnormal conditions. The method includes charging the battery to a fully charged state, then, applying a known load to the battery and discharging the battery to a designated depth of voltage. The known load is removed from the battery, and the open circuit voltage (OCV) of the battery is monitored over time to determine an elapsed time over which the OCV recovers to a designated recovery voltage value. Based on the determined elapsed time, the method determines if the battery has a dangerous condition.

### FIELD OF THE INVENTION

The disclosure relates to techniques for monitoring of hazardous conditions in batteries in advance, as well as systems and integrated circuits performing such monitoring.

### BACKGROUND

For battery-powered devices that use lithium-ion batteries, such as medical devices, portable devices, industrial devices, and electric vehicles, it is a strong requirement that hazardous conditions within the lithium-ion battery be detected in advance. While various failure conditions can exist within such batteries, battery aging and the associated increase in internal resistance are an important cause of failure conditions. Further, batteries with manufacturing flaws have a greater tendency for failures, which increases more quickly over time than for normal batteries.

Prior art battery techniques for monitoring hazardous conditions in a battery tend to focus on battery temperature as the main indicator of a possible hazardous condition. However, such techniques often fail to detect potentially dangerous conditions within the battery in time to prevent hazardous conditions caused by thermal runaway of a battery.

### BRIEF DESCRIPTION OF THE DRAWINGS

The present disclosure may be better understood, and its numerous features and advantages made apparent to those skilled in the art by referencing the accompanying drawings, in which:

FIG. 1 illustrates in block diagram form a number of conditions which tend to cause failure in batteries;

FIG. 2A illustrates in diagram form how a battery loses capacity over time;

FIG. 2B shows a graph of battery capacity versus the internal resistance of a battery illustrating the capacity loss depicted FIG. 2A;

FIG. 3A shows a block diagram of a system including a hazard detection circuit for a battery;

FIG. 3B shows two graphs illustrating load current for the battery of FIG. 3A during hazard detection, and battery voltage under various conditions for the battery of FIG. 3A;

FIG. 4 illustrates in block diagram form a system including an integrated circuit for performing battery hazard detection;

FIG. 5 shows a flowchart of a process detecting a hazard in a battery;

FIG. 6 shows a graph illustrating a dangerous level for an open circuit voltage recovery period;

FIG. 7 shows a graph illustrating open circuit voltage recovery periods for different battery temperatures;

FIG. 8 shows a graph illustrating a battery open circuit voltage versus battery state of charge;

FIG. 9 shows a chart illustrating a voltage drop due to the controlled battery discharge, and a diagram illustrating the same voltage drop with a battery and load; and

FIG. 10 illustrates in block diagram form a system including a constant load circuit;

The use of the same reference symbols in different drawings indicates similar or identical items. Unless otherwise noted, the word “coupled” and its associated verb forms include both direct connection and indirect electrical connection by means known in the art, and unless otherwise noted any description of direct connection implies alternate embodiments using suitable forms of indirect electrical connection as well.

### DETAILED DESCRIPTION OF ILLUSTRATIVE EMBODIMENTS

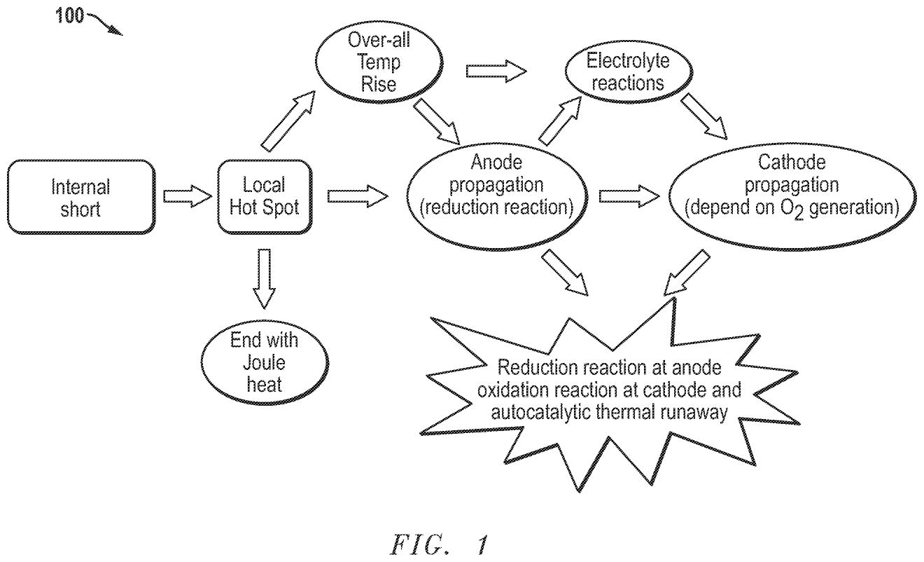

FIG. 1 shows a block diagram of a number of conditions 100 which tend to cause failure in batteries. Generally as shown, battery failures are caused by internal shorts which result from various manufacturing flaws or aging. Such shorts create a hot spot within the battery. Such heat may be dissipated as infrared (IR) for a time, but will often cause a large area of high heat as temperatures within the battery increase to over 100° C. This results in anode propagation, a reduction reaction. Electrolyte reactions may also occur within the battery. As the heat increases, cathode propagation may also occur within the battery depending on O₂ generation. When anode propagation or cathode propagation occurs, thermal runaway often results within the battery due to increased power dissipation.

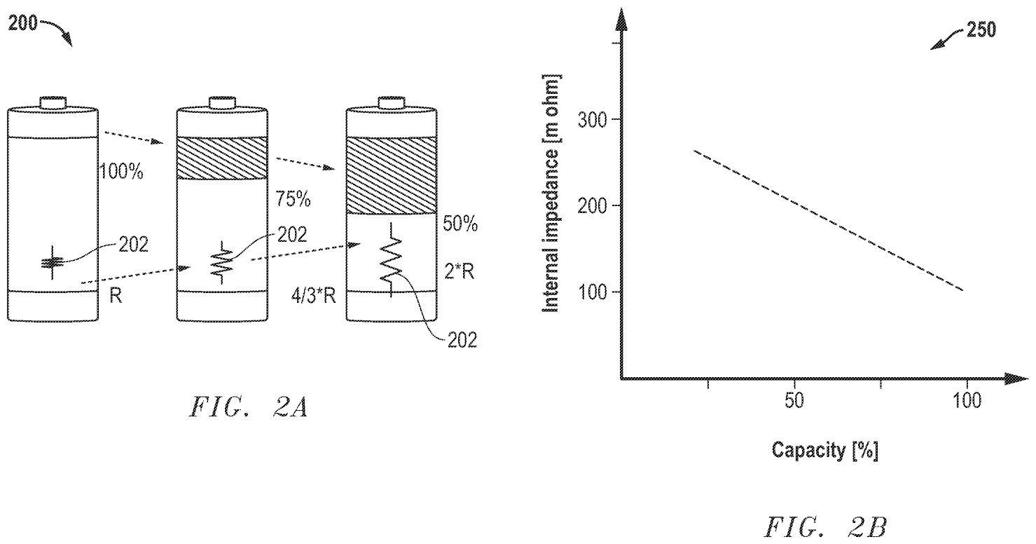

FIG. 2A illustrates in diagram form how a battery loses capacity over time. A new battery 200 is depicted with 100% capacity. In this condition, battery 200 has a small internal resistance 202 as depicted by the small resistor symbol with a resistance of R. As the battery ages, the internal resistance increases and the battery capacity decreases. Shown in the middle is an older battery with a 75% capacity (versus the original capacity). The internal resistance 202 has increased to about 4/3 *R. Finally on the right an older battery is depicted with a 50% capacity. At this age, the internal resistance 202 will have a value of about 2R.

FIG. 2B shows a graph 250 of battery capacity versus the internal resistance of a battery illustrating the capacity loss depicted FIG. 2. The internal resistance is shown on the vertical axis in milli-ohms, and the capacity is shown on the horizontal axis as a percentage. As can be seen, generally the internal resistance increases with a linear relationship as the battery capacity decreases.

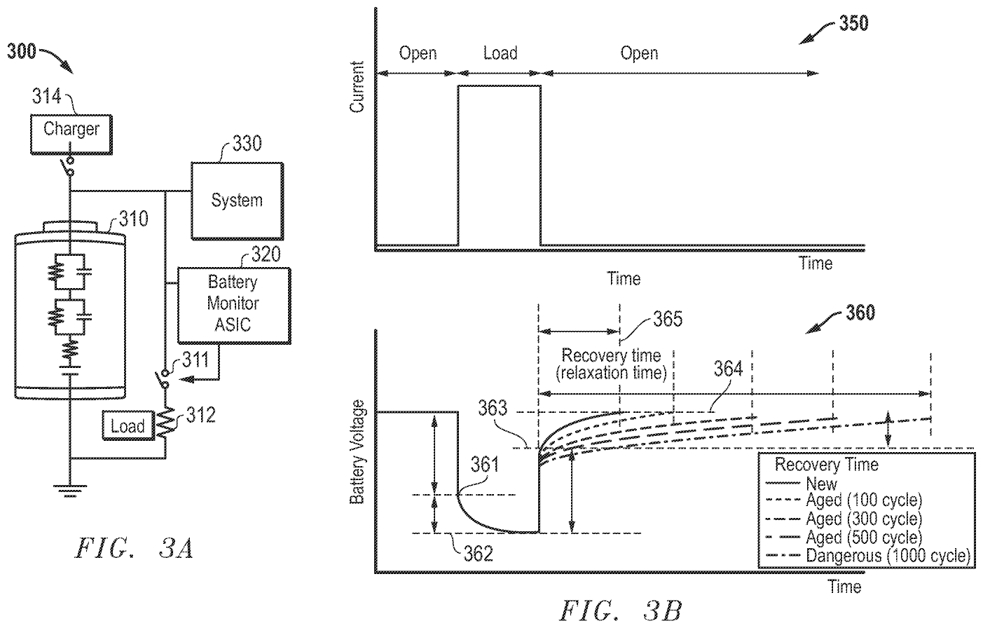

FIG. 3A illustrates in block diagram form a system 300 including a hazard detection feature according to some embodiments. System 300 may be embodied in a portable device powered by a battery, but may also be embodied in a non-portable device with a fixed electrical supply that includes a backup battery. System 300, in this implementation, generally includes a battery 310, a load control switch 311, a load resistor 312, a charger 314, a battery monitor application-specific integrated circuit (ASIC) 320, and an application system 330.

Battery 310 is a lithium battery such as a lithium-ion or lithium-polymer battery in this implementation, but batteries of other types may also be used. Battery 310 is shown an ideal voltage source in series with a resistance, and includes a positive terminal connected to a positive voltage supply rail and a negative terminal connected to a negative voltage supply rail. A thermistor or other temperature sensor (not separately shown) may be included, thermally coupled to battery 310 for monitoring its temperature. Charger 314 includes a positive terminal connected to the positive voltage supply rail and a negative terminal connected to the negative voltage supply rail. Further, in some embodiments a separate battery protection IC may be included in the battery module which operates to disconnect the battery from the circuit in the event of thermal runaway.

As shown in this simplified form, battery monitor ASIC 320 and system 330 are supplied with power by battery 310. Battery monitor ASIC 320 monitors the voltage of battery 310, and has an output connected to activate and deactivate load control switch 311. Charger 314 operates to charge battery 314 from an external power source. While in this embodiment, charger 314 and battery monitor ASIC 320 are separate circuit modules, in some embodiments they may be integrated into a single battery controller integrated circuit (IC).

In operation, as application system is operated by a user, battery 310 occasionally requires battery charging by charger 314. Battery 310 may be an operating battery for a portable device, or a backup battery for a device requiring backup power, such as a medical device that requires high reliability. Battery monitor ASIC 320 generally monitors the health of battery 310 and includes a test capability for detecting hazardous conditions in battery 310. The test capability includes a process for detecting premature aging and other hazardous conditions of the battery.

As further described below, the test process generally includes charging the battery to a fully charged state, then, activating load control switch 311 to apply load resistor 312 as a load to battery 310. This discharges the battery to a designated state-of-charge. The current through load resistor 312 for such a test process is depicted in FIG. 3B in graph 350, which shows current on the vertical axis and time on the horizontal axis. As shown, in general operation there is no load current through load resistor 312 as shown in the time labelled “Open”. Then the load is applied as shown by the time labelled “Load”. When the designated state-of-charge is reached, the process removes load from battery 310 as shown in FIG. 3B by the second time labelled “Open”. At this point, the process starts a timer, and monitors the open circuit voltage (OCV) of battery 310 over time. The process determines an elapsed time over which the OCV recovers to a designated recovery voltage value, and based on the determined elapsed time, determining if the battery has a dangerous condition.

Graph 360 of FIG. 3B depicts the battery voltage of battery 310 over the same time period shown in graph 350, and is aligned in time with graph 350 to illustrate the effect of the current load on the battery voltage. The vertical axis shows the battery voltage, and the horizontal axis shows time. As can be seen, from the open circuit voltage, when the load is applied, the battery voltage drops very quickly to a loaded voltage 361, and then slowly drops further as the battery is discharged to a second voltage 362. When the load is removed, the battery voltage recovers quickly to a third unloaded voltage 363, which varies depending on the age and condition of the battery, as depicted by the multiple graphs showing the battery voltage recovering from various starting points at differing rates. Following this, the OCV recovers over time to the designated recovery voltage 364. The multiple graphs illustrate an example of the OCV recovery time for a new battery, a battery aged 100 charging/discharging cycles, a battery aged 300 charging/discharging cycles, a battery aged 500 charging/discharging cycles, and a battery aged 1000 charging/discharging cycles, which is indicated to be dangerous. In some embodiments, the recovery time may be normalized with respect to the recovery time for a new battery, labelled 365, as further described below.

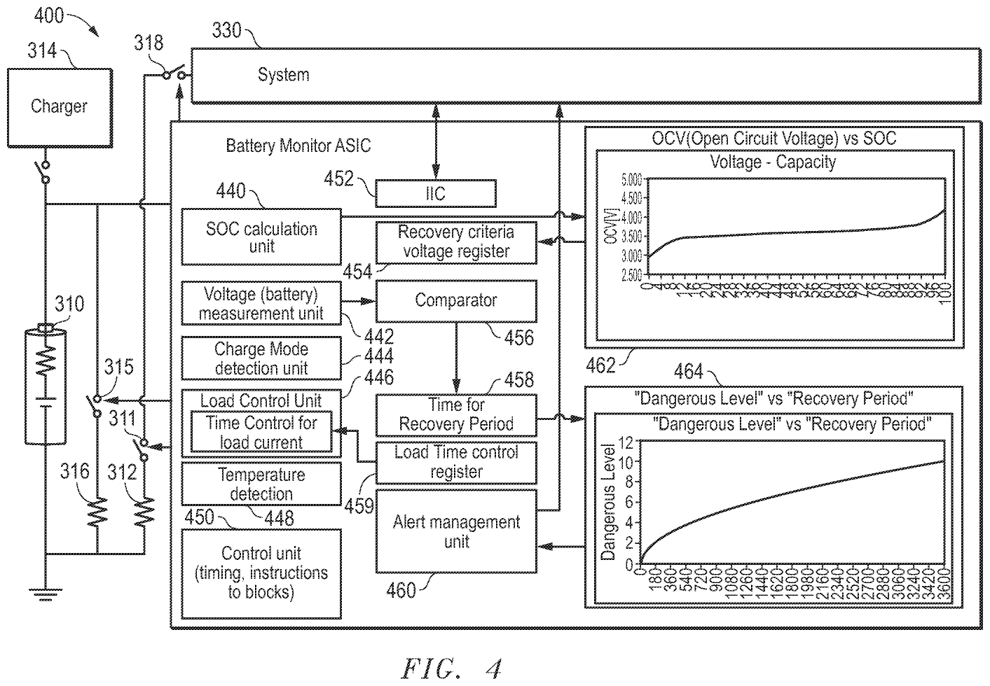

FIG. 4 illustrates in block diagram form a system 400 showing more detail of the battery monitor ASIC 320 of FIG. 3. System 400 generally includes battery 310, load control switch 311, load resistor 312, charger 314, a second load control switch 315, a second load resistor 316, a system power switch 318, battery monitor ASIC 320, and application system 330.

Battery monitor ASIC 320, in this implementation, includes a state-of-charge (SOC) calculation unit 440, a battery voltage measurement unit 442, a charge mode detection unit 444, a load control unit 446, a temperature detection unit 448, a control unit 450, an Inter-Integrated Circuit (IIC or I²C) bus interface 452, a recovery criteria voltage register 454, a comparator 456, a timer 458, a load time control register 459, an alert management unit 460, an OCV vs. SOC data set 462, and a dangerous level vs. recovery period data set 464. Generally, battery monitor ASIC 320 is implemented with a mix of analog and digital circuitry, flash memory, processor cores, and static random-access memory (SRAM). While an ASIC is used in this embodiment, other implementations may use a programmable logic device or other suitable integrated circuit or combination of circuits.

State-of-charge (SOC) calculation unit 440 calculates a current SOC for the battery based on the battery voltage and capacity of the battery, which varies over time. The current SOC is employed to access OCV vs SOC data set 462 to determine current recovery voltage parameters for battery 310. Battery voltage measurement unit 442 receives the voltage on the positive battery terminal and converts it to a digital value for tracking the battery voltage. Charge mode detection unit 444 determines whether battery 310 is charging or discharging, and may detect a charging mode such as constant current (CC) mode or a constant voltage (CV) mode. This information is used by control unit 450 for determining when a battery test process may be activated, and to track the battery age.

Load control unit 446 has an output connected to the control load control switch 311 for applying and removing load resistor 312, a second output connected to control second load control switch 315 to apply and remove second load resistor 316 during the battery test cycle, and a third output connected to system power switch 318 for removing the system load from the circuit during the battery test cycle. Second load control switch 315 and second load resistor 316 are connected in parallel to load control switch 311 and load resistor 312. In this embodiment, two load resistors are employed to better control the load current from battery 310. Load control unit also includes a time control unit for controlling the time a load current is applied. Load time control register feeds a configured value to the time control unit for determining how long a battery load is applied.

Temperature detection unit 448 receives a signal from a temperature sensor for battery 310, and converts the signal to a digital temperature value to indicate the battery temperature.

Control unit 450 is generally coupled to the other depicted circuit blocks and includes an interface to a random-access memory (RAM) and a non-volatile memory such as a FLASH memory, which are not separately shown but may be implemented on-chip or off-chip. Control unit 450 generally controls the timing of operation for the other circuit blocks and executes instructions for performing the battery test process as described herein, as well as other battery management processes which are not depicted because they are not relevant to the present disclosure. Control unit 450 in this embodiment is a processor core with input/output circuitry for interfacing with the various depicted components. While a processor core is used in this embodiment, other embodiments may instead employ digital logic, for example programmable logic configured with a hardware description language (HDL) such as VHDL.

IIC bus interface 452 is provided for connecting with application 330. IIC bus interface 452 is used to load and update software to battery monitor ASIC 320, and load and update the data sets 462 and 464 for specific battery types installed in the system, as well as for reporting hazard conditions back to application system 330.

Recovery criteria voltage register 454 holds a recovery voltage value for the OCV voltage tracked in the battery test process, for example voltage 364 (FIG. 3). This value is updated from the OCV vs. SOC data set based on the age of the battery to provide the recovery voltage level suitable for the current capacity of battery 310 as it ages. Comparator 456 compares the battery voltage to the recovery voltage value held in register 454, and may be implemented digitally. Timer 458 is used in the battery test process to determine the elapsed time over which the OCV recovers to a designated recovery voltage value. Alert management unit 460 compares the recovery time measured by timer 458 to a time from data set 464 providing a threshold value for indicating whether the recovery period for the battery is over a dangerous level.

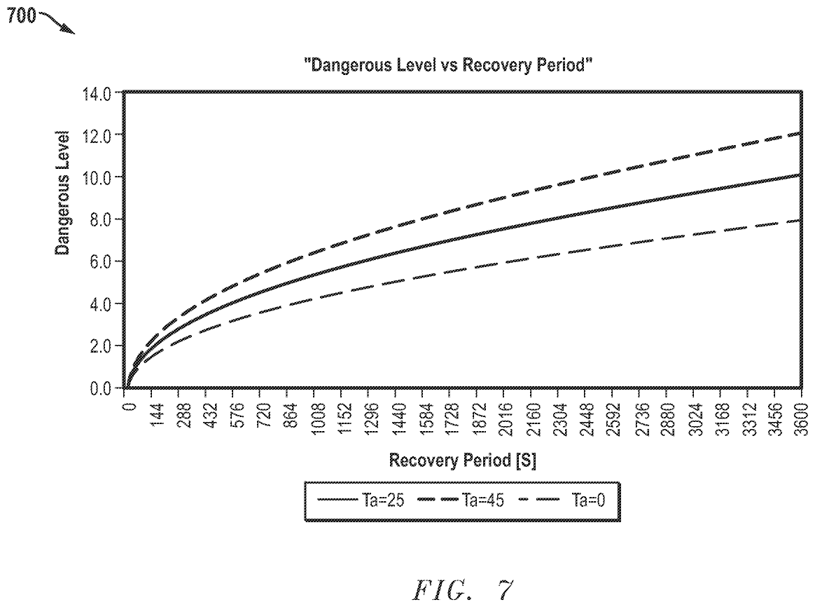

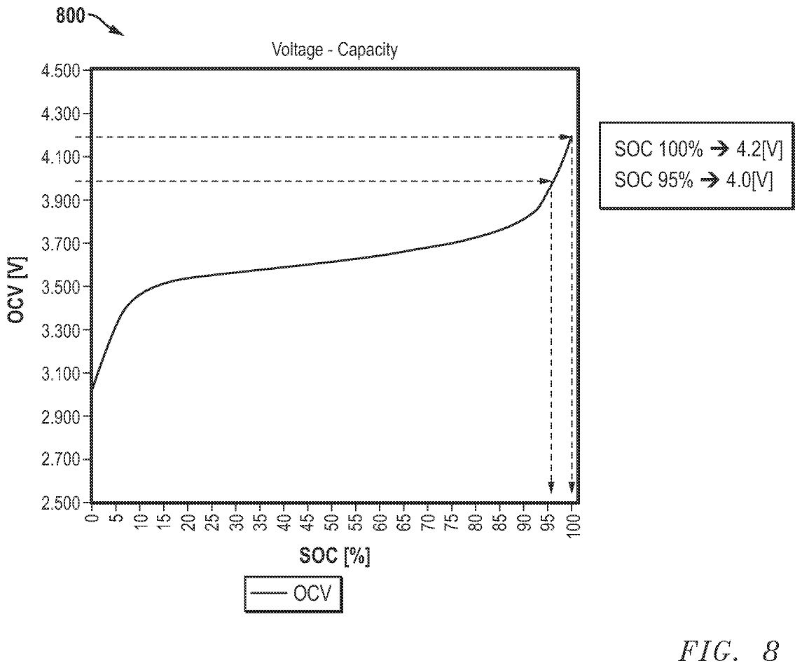

OCV vs. SOC data set 462 is stored in non-volatile memory and contains open circuit voltage data for battery 310, as further described with respect to FIG. 8. Dangerous level vs recovery period data set 464 is stored in non-volatile memory and holds unsafe OCV recovery time data for multiple battery temperatures, as further described with respect to FIG. 7. Alert management unit 460 accesses data set 464 to obtain a threshold value for determining whether battery 310 has an unsafe condition.

While this particular hardware design is given as an example, it should be apparent after appreciating this description that various other implementations can use different hardware to achieve the battery monitoring functionality discussed below. For example, a purely microcontroller-based implementation may be used in which a controller performs all the functions discussed after measurements are digitized and fed to the controller. Further, as discussed above, in some implementations, programmable logic may be employed using a HDL.

In operation, control unit 450 controls battery monitor ASIC 320 to perform a battery test process, as further described below, to detect battery fault conditions or dangerously aged batteries in advance, in order to avoid dangerous situations such as lithium battery explosion or fire. Many systems can benefit from the use of battery hazard monitoring techniques herein, such as handheld battery-powered surgical tools, other medical equipment, personal electronics, electric vehicles, and battery powered industrial equipment.

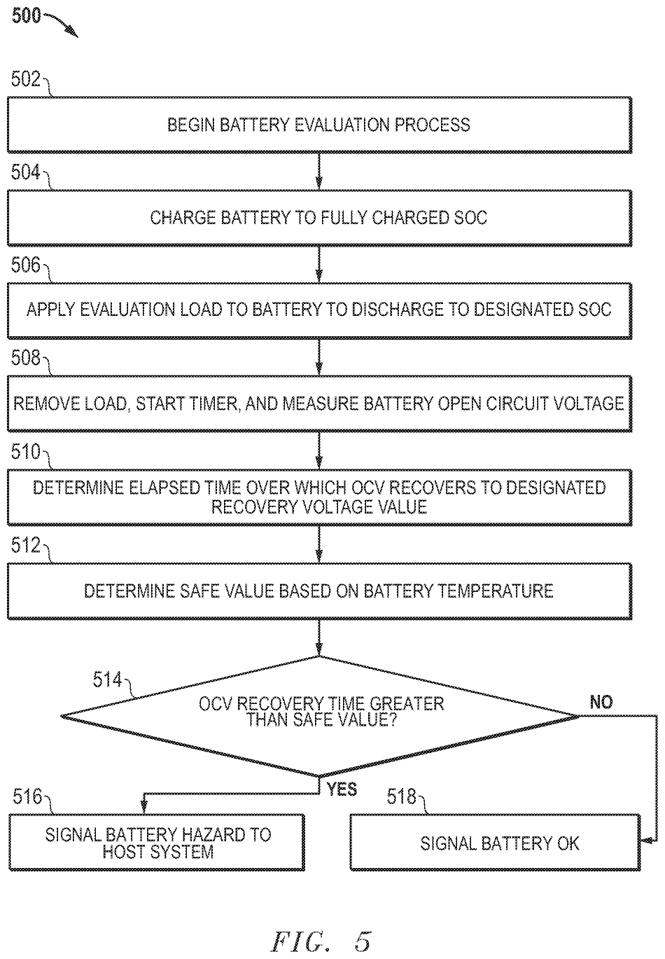

FIG. 5 shows a flowchart 500 of a process for testing a battery according to some embodiments. The process is suitable for performance by the battery monitor ASIC of FIG. 4, or other suitable battery monitoring circuits, for monitoring a battery for dangerous conditions over the life of the battery.

The process begins at block 502 where the system initiates a new battery evaluation process. The initiation may happen periodically over time, upon activation by a user, or at other intervals such as a designated number of charge and discharge cycles of the battery. At block 504, the process charges the battery to a fully charged state. The full charge level voltage is generally determined by battery specification and charger IC support this full charge level voltage (high side voltage of the battery with 100% SOC). Generally, it is preferred to use the full charge level voltage, which provides a high side voltage of the battery with 100% SOC, as starting point criteria voltage for the battery test cycle. In some embodiments, it is acceptable to use another SOC, such as 90%, as a starting point. However, in such a case, the battery test process needs to obtain the battery voltage of SOC 90% by referring the open circuit voltage vs SOC characteristic curve.

At block 506, the process applies applying a known evaluation load to the battery and discharging the battery to a certain depth of voltage and a designated state-of-charge. Here, the depth of the voltage is determined by the load current, and the designated state-of-charge (SOC) is determined by the load current by time. The load current is selected to provide a deep enough discharge cycle that the OCV recovery voltage time is accurately measurable. In one example scenario, the full charge voltage level of the battery (100% SOC) is 4.2V, and the battery internal resistance is 0.25Ω. If the load resistor's resistance R=0.8Ω, the current flow becomes 4 A=4.2 V/(0.25Ω+0.8Ω) which is the known load, and depth of the voltage drop illustrated in FIG. 3B will be 1V=0.25Ω*4A. This known load current drawn over the load period of time leads to a designated SOC decrease. For example, if battery capacity is 1000 mAh, the battery has a capability to output 1A (1000 mA) for 36000 seconds (1 hour), a 4A known load current for by 45 seconds provides a charge decrease of 4A*45s), which is the 5% of the total coulomb charge of (1A*3600[S]), resulting in a battery SOC of 95%. While this example embodiment uses a 5% discharge to provide a state-of-charge of 95%, in other embodiments other values may be used. In some embodiments, the designated state-of-charge is a discharge of between 2% and 15% of a capacity of the battery. With this discharge (load), the battery SOC becomes 98%-85%. In some embodiments, the designated state-of-charge is a discharge of between 4% and 6% of a capacity of the battery, and the battery SOC becomes 96%-94%. The known load may be a load resistor or a constant load circuit. As shown in FIG. 4, multiple resistors may be used to provide limited control over the load current. In some embodiments, a load resistor or constant load circuit provides a load sized such that it would provide a total discharge of the battery over a designated time such as 0.5 hours, 1 hour, or 2 hours (known as a 2C, 1C or 0.5C load). Using this load, the battery discharge (a decrease in coulomb charge of current in Amps*time) is controlled by load current and load time which time is stored in “load time control register” 470 in FIG. 4. The load time is selected, paired with the load size, to provide a desired depth of discharge within a reasonable time for conducting the test, for example between 45 second and 90 second, for example. In one embodiment, voltage depth of the battery is controlled by a constant load circuit. In another embodiment, voltage depth of the battery is controlled by the load resistor selection.

At block 508, the process removes the known load from the battery, starts a timer, and monitoring the OCV of the battery over time. Monitoring the OCV means that no load is applied to the battery during this portion of the process. At block 510, the process determines an elapsed time over which the OCV recovers to a designated recovery voltage value. This recovery time relates to the age of the battery. Further, batteries with dangerous conditions often exhibit a dangerous recovery time even when they are younger than the depicted dangerous recovery time for a battery aged 1000 cycles.

At block 512, the process determines a safe value for the recovery time based on the battery temperature. In system 400 of FIG. 4, this step includes accessing dangerous level vs recovery period data set 464 to obtain a threshold for safe recovery periods. At block 514, the process checks whether the measured OCV recovery time is greater than the safe value threshold. If so, the process goes to block 516 where it is signals to the host system that the battery has a hazardous or dangerous condition. If not, the process goes to block 518 where it signals that the battery is okay.

The process may also include configuring the designated state of charge by writing a value to one of a register and a memory location, such as recovery criteria voltage register 454 of FIG. 4. This value is then accessed before applying the load to the battery to determine the designated state of charge. The recovery voltage (363, FIG. 3B) may also be configured based on the age of the battery by accessing a data set such as OCV vs. SOC data set 462, containing suitable recovery voltages for the designated state of charge at different battery ages.

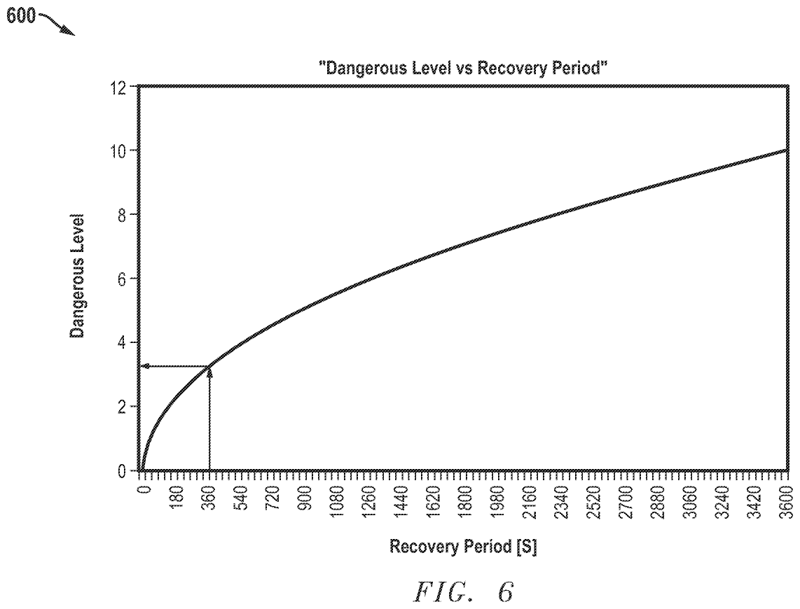

FIG. 6 shows a graph 600 illustrating a dangerous level for an open circuit voltage recovery period. As discussed above, the open circuit voltage recovery period is the recovery time after the battery load is removed, the time over which the battery voltage will recover towards open circuit voltage point from the depth of the voltage when current load being applied. The vertical axis shows a scale normalized to the recovery time of a new battery. That is, 1 is the recovery time of a new battery, 2 is twice the recovery time of a new battery, etc. The horizontal axis shows time. The dangerous level is selected in this embodiment at a normalized value of 3.2, indicating that a battery is considered to have dangerous conditions if the recovery time is greater than 3.2 times that of a new battery.

FIG. 7 shows a graph 700 illustrating open circuit voltage recovery periods for different battery temperatures. Graph 700 is normalized like that of FIG. 6, and shows graphs of open circuit recovery times for ambient temperatures (Ta) of 25 degrees C., 45 degrees C., and zero degrees C. As can be seen, the recovery times vary based on temperature, and data set 462 preferably contains values for a full range of battery operating temperatures.

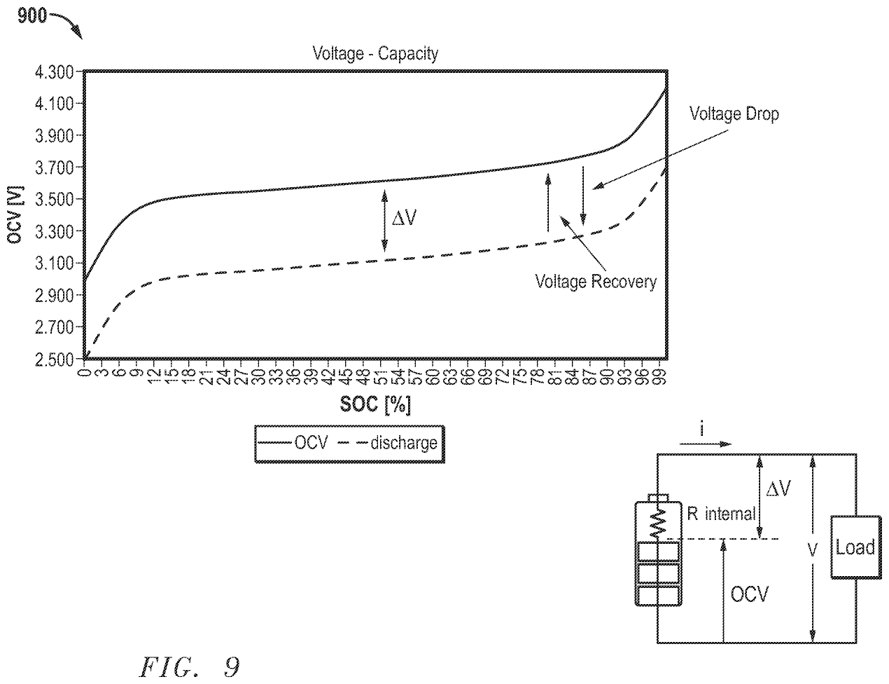

FIG. 8 shows a graph 800 illustrating a battery open circuit voltage versus battery state of charge. The vertical axis shows the battery OCV, and the horizontal axis shows the SOC in percentage. Graph 800 depicts one OCV curve for a new battery, which generally is not changed in shape as the battery ages and loses capacity. The change in voltage, ΔV, is illustrated further in FIG. 9.

FIG. 9 shows a chart 900 illustrating a voltage drop due to the controlled battery discharge, and a diagram 910 illustrating the same voltage drop with a battery and load. As can be seen in diagram 910, if the current “i” is drawn from the battery by applying the load, the battery voltage V shifts downward by ΔV because the battery has an internal resistance, with the battery voltage drop due to internal resistance and current load recovering slowly. The OCV voltage curve is shown for a battery, along with a discharge curve, labelled “discharge”, which shows the battery voltage after the load is applied during the battery test cycle. As can be seen by the ΔV between the two curves, the battery voltage is shifted downwards by current load. The battery voltage then recovers gradually towards upwards after the current load is removed. The recovery time is varies with battery aged level or damaged level, or dangerous level such data for batteries of multiple ages. This data is employed to determine the recovery voltage for batteries of various ages.

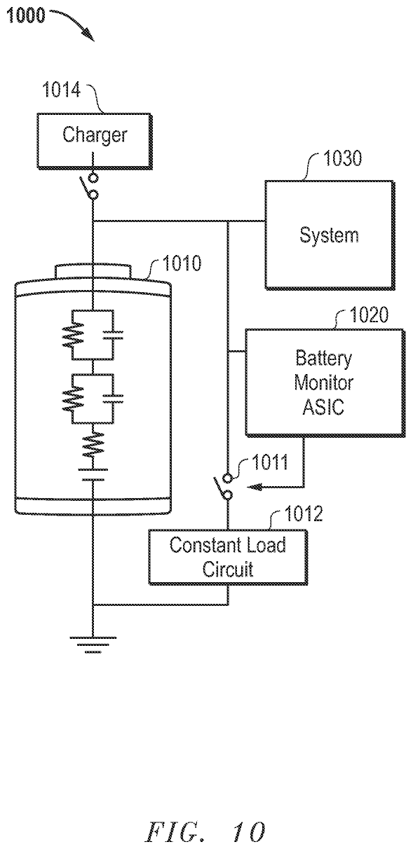

FIG. 10 illustrates in block diagram form a system 1000 including a constant load circuit. System 1000, is similar to system 300 of FIG. 3, but uses a constant load circuit 1012 rather than a load resistor. System 1000 generally includes a battery 1010, a load control switch 1011, constant load circuit 1012, a charger 1014, a battery monitor application-specific integrated circuit (ASIC) 1020, and an application system 1030.

Constant load circuit 1012 is preferably a configurable constant current load which can be controlled by battery monitor ASIC 1020 to draw a current of a designated level. When this circuit is used to implement the process of FIG. 5, the constant load circuit provides more precise control of the discharge process, because a load resistor draws slightly less current as the battery voltage drops.

Thus, various embodiments of a battery monitor circuit, an apparatus including such a battery monitor, and a corresponding method have been described. The various embodiments provide hazard monitoring for a battery. Known techniques of tracking battery aging and failure can be inaccurate and increase risk of catastrophic failures. Embodiments of the present disclosure improve the monitoring accuracy by monitoring the battery temperature during charge actions, and detecting abnormal temperature ramp-up for designated changes in the battery state-of-charge, comparing the temperature increase against data indicating abnormal battery performance.

The above-disclosed subject matter is to be considered illustrative, and not restrictive, and the appended claims are intended to cover all such modifications, enhancements, and other embodiments that fall within the true scope of the claims. For example, the ΔSOC data may be stored in various forms. As another example, while measuring the battery temperature and ambient temperature is preferred in order to properly attribute temperature changes to charging action, in some embodiments where ambient temperature is not expected to change significantly, the ambient temperature is not measured and the temperature changes are based only on battery temperature readings.

Thus, to the maximum extent allowed by law, the scope of the present invention is to be determined by the broadest permissible interpretation of the following claims and their equivalents, and shall not be restricted by the forgoing detailed description.

1. A method of monitoring a battery comprising:
charging the battery to a fully charged state;
then, applying a known load to the battery and discharging the battery to a designated voltage depth of the battery;
then, removing the known load from the battery, starting a timer, and monitoring an open circuit voltage (OCV) of the battery over time;
determining an elapsed time over which the OCV recovers to a designated recovery voltage value; and
based on the determined elapsed time, determining if the battery has a dangerous condition.

2. The method of claim 1, further comprising:
configuring the designated voltage depth by writing a designated state of charge value to one or more of a register and a memory location; and
before applying the known load to the battery, accessing the value to obtain the designated state of charge.

3. The method of claim 1, further comprising:
after charging the battery to the fully charged state, measuring a temperature of the battery; and
to determine if the battery has a dangerous condition, accessing a data set stored in memory including unsafe OCV recovery time data for multiple temperatures, wherein determining if the battery has a dangerous condition is further based on the temperature of the battery.

4. The method of claim 1, wherein:
the designated voltage depth of the battery is controlled by a constant load circuit.

5. The method of claim 1, wherein:
the designated voltage depth of the battery is controlled by selecting a value of a load resistor.

6. The method of claim 1, wherein:
the known load is a load resistor sized to provide a total discharge level of the battery over a time between 0.5 hours and 2 hours.

7. The method of claim 1, wherein the method is performed on an application-specific integrated circuit (ASIC) located in a host system including the battery.

8. A circuit for monitoring a battery comprising:
a battery load comprising one of a resistor and a constant load circuit;
a switch operable to apply the battery load to the battery;
a timer; and
a hazard detection circuit operable to:
cause the battery to be charged to a fully charged state;
then, activate the switch to apply the battery load to the battery and discharge the battery to a designated voltage depth of the battery;
then, deactivate the switch to remove the load from the battery, start the timer, and monitor an open circuit voltage (OCV) of the battery over time;
determine an elapsed time over which the OCV recovers to a designated recovery voltage value; and
based on the determined elapsed time, determine if the battery has a dangerous condition.

9. The circuit of claim 8, further comprising:
one of a register and a memory location rewriteable to hold a configurable value for the designated voltage depth.

10. The circuit of claim 8, further comprising:
a battery temperature sensor; and
a non-volatile memory holding a data set including unsafe OCV recovery time data for multiple battery temperatures,
wherein determining if the battery has an unsafe condition further includes accessing the data set based on a battery temperature.

11. The circuit of claim 8, wherein:
the designated voltage depth of the battery is controlled by a constant load circuit.

12. The circuit of claim 8, wherein:
the designated voltage depth of the battery is controlled by selecting a load resistor value.

13. The circuit of claim 8, wherein:
a load time for which the battery load is applied is controlled by a load time control register.

14. An apparatus comprising:
a battery, an application system powered by the battery, and a charger coupled to the battery; and
a battery load comprising one or more of a resistor and a constant load circuit;
a switch operable to apply the battery load to the battery;
a timer; and
a hazard detection circuit operable to:
cause the battery to be charged to a fully charged state;
then, activate the switch to apply the battery load to the battery and discharge the battery to a designated voltage depth of the battery;
then, deactivate the switch to remove the load from the battery, start the timer, and measure an open circuit voltage (OCV) of the battery over time;
determine an elapsed time over which the OCV recovers to a designated recovery voltage value; and
based on the determined elapsed time, determine if the battery has a dangerous condition.

15. The apparatus of claim 14, further comprising:
one of a register and a memory location rewriteable to hold a configurable value for the designated voltage depth.

16. The apparatus of claim 14, further comprising:
a battery temperature sensor thermally coupled to the battery and communicatively coupled to the hazard detection circuit; and
a non-volatile memory holding a data set including unsafe OCV recovery time data for multiple battery temperatures,
wherein determining if the battery has an unsafe condition further includes accessing the data set based on a battery temperature.

17. The apparatus of claim 14, wherein:
the designated voltage depth of the battery is controlled by a constant load circuit.

18. The apparatus of claim 14, wherein:
the designated voltage depth of the battery is controlled by selecting a value of a load resistor.

19. The apparatus of claim 14, wherein:
a load time for which the battery load is applied is controlled by a load time control register.

20. The apparatus of claim 14, wherein:
the hazard detection circuit is formed in an application-specific integrated circuit (ASIC) located in a host system including the battery.
